(19) United States
(12) Patent Application Publication
(10) Pub. No.: US 2004/0146739 A1
(43) Pub. Date: Jul. 29, 2004

(54) Laser coating of a seal surface used in an oil refinery

(76) Inventors: Tapani Karhinen, Kirkkonummi (FI); Jari Lyytinen, Porvoo (FI)

Correspondence Address: BIRCH STEWART KOLASCH & BIRCH, PO BOX 747, FALLS CHURCH, VA, 22040-0747, US

(21) Appl. No.: 10/479,058

(22) PCT Filed: May 28, 2002
(86) PCT No.: PCT/FI02/00459

(30) Foreign Application Priority Data
May 28, 2001 (FI) 20011116

(51) Int. Cl. C23C 14/30; B32B 15/18

(52) U.S. Cl. 428/679; 427/596; 428/680

(57) ABSTRACT

The invention relates to a method for coating a seal surface (1) used at an oil refinery by a coating layer (4) of a nickel-based material. In the method according to the invention, the coating layer (4) is formed using a laser coating method. The invention also relates to a seal surface (1) for use at an oil refinery and having a coating layer (4) of a nickel-based material applied theron. In a seal surface (1) according to the invention, the coating layer (4) is formed using a laser coating method.

The invention relates to a method according to the preamble of claim 1 for coating a seal surface used in an alkylation process at an oil refinery with a coating layer of a nickel alloy material. The invention also relates to a seal surface coated with a coating layer of a nickel alloy material for use in an alkylation process at an oil refinery.

Hydrofluoric acid (HF) is an important basic chemical commonly used in the industry. For instance, in alkylation units of oil refineries this acid is used as a catalyst. Hydrofluoric acid attacks most metals and metal alloys in an aggressively corrosive manner. The rate of corrosion is affected, among other factors, by the concentration, temperature and water content of the acid. The corrosion rate may additionally be accelerated by impurities occurring in the process. In particular, seal surfaces used in an alkylation unit, such as the seal surfaces of flanges and valves, are subject to corrosion.

Construction materials commonly used in the handling of hydrofluoric acid are carbon steels and, in particularly demanding cases, nickel alloys of which particularly well known is a nickel-copper alloy marketed under tradename Monel 400. In fact, carbon steel parts have generally been replaced in applications most severely subjected to corrosion by similar components made from a nickel-based alloy. However, nickel alloys have a limited use in plural sites due to their high, even hundred-fold price and weaker structural properties in regard to carbon steels.

To improve their corrosion resistance, carbon steel parts may also be protected by depositing a coating layer of a nickel alloy material thereon. Herein, the coating is applied to the surface of the base material generally by spraying or immersing the object to be coated into a bath of molten coating material. A disadvantage of these methods is that the coating layer contains pores or other defects via which the corrosive medium can penetrate into the interface between the coating and the base material, whereby local corrosion at the points of the base material subjected to the attack of the corrosive material may proceed extremely rapidly. To provide an unpenetrable coating layer, it must be made thick with the inevitable consequence, that the coated part often requires machining after the application of the coating layer. Hence, conventional coating methods are often awkward in the application of a sufficiently solid and thin coating layer.

It is an object of the present invention to provide a novel type of coating method for applying a coating of a nickel alloy material onto a seal surface used in an alkylation process at an oil refinery. It is a further object of the invention to provide a novel kind of seal surface which is suited for use in an alkylation process at an oil refinery and is coated with a nickel-alloy material.

The goal of the invention is achieved by means of forming the coating layer with the help of a laser coating method wherein the nickel alloy coating material is melted on surface of the base material of a seal with the help of a laser beam.

More specifically, the method according to the invention is characterized by what is stated in the characterizing part of claim 1.

Furthermore, the seal surface according to the invention is characterized by what is stated in the characterizing part of claim 6.

The invention offers significant benefits.

The coating layer applied by means of laser coating is solid and free from pores inasmuch the operating parameters of laser coater equipment can be effectively controlled during the entire coating process. This makes it possible to produce a coating layer free from pores, whereby the corrosion resistance of the coated seal surface is improved substantially as compared with coatings applied by conventional thermal coating methods. Due to the improved corrosion resistance of such seal surfaces, the alkylation unit can be operated at lower maintenance needs, reduced service costs and higher safety.

In the following, the invention is described in more detail with reference to the appended drawings in which:

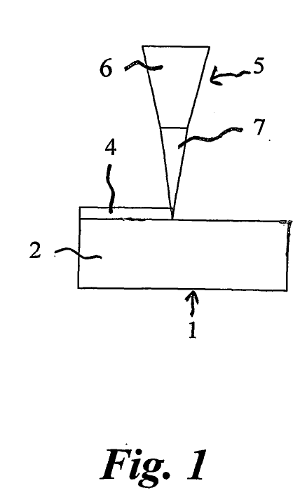

FIG. 1 is a schematic diagram of laser coater equipment and a seal surface to be coated;

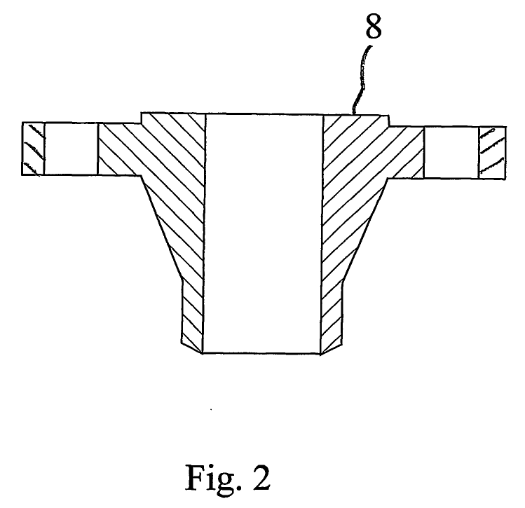

FIG. 2 is a longitudinally sectioned view of the flange of a pipe;

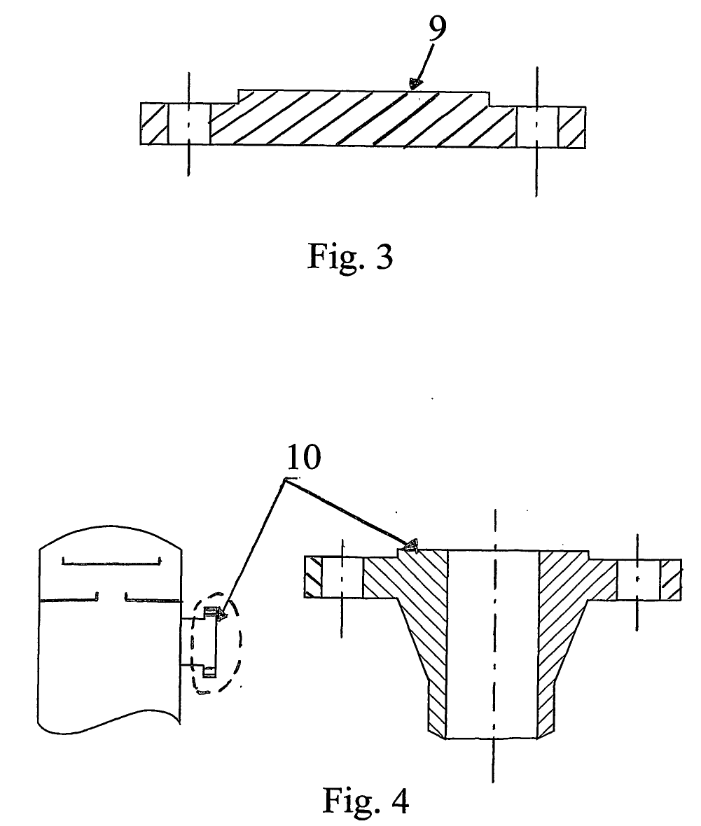

FIG. 3 is a longitudinally sectioned view of a blind flange;

FIG. 4 is a partially sectioned view of a vessel with a partially enlarged view of the seal surface of a manhole cover; and

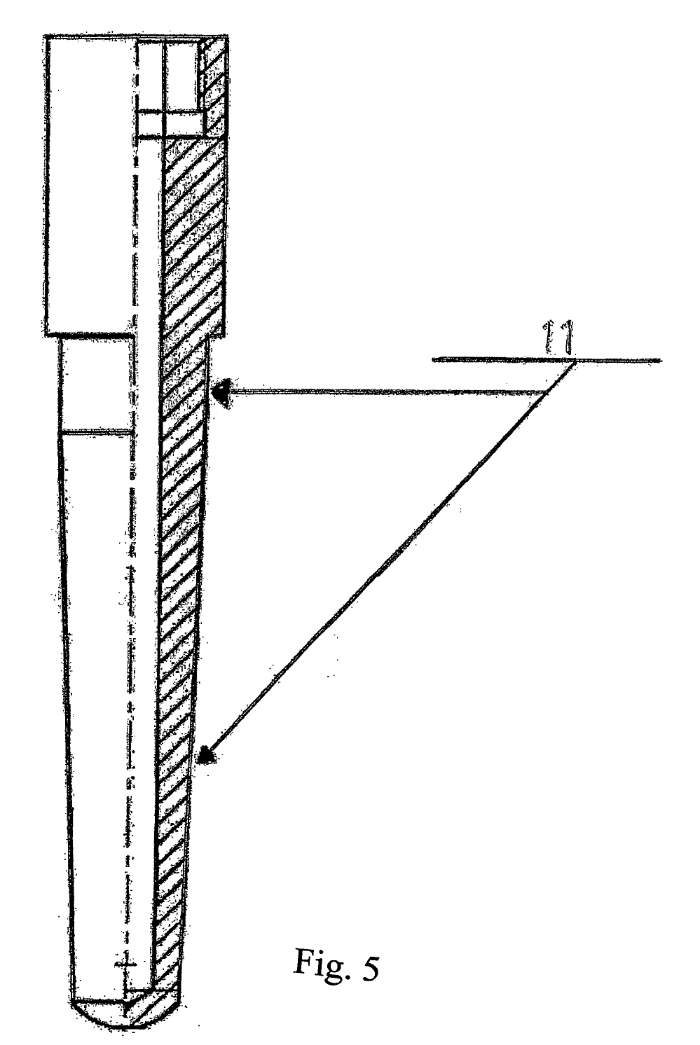

FIG. 5 is a longitudinally sectioned view of a vapor pocket.

In FIG. 1 is shown the application technique of a coating layer onto a seal surface 1 suited for use in the alkylation unit of an oil refinery. During the operation of the alkylation unit, the seal surface 1 is mated with another seal surface and, the seal surfaces 1 will become in contact with a hydrofluoric acid (HF) employed in the alkylation process as a carrier medium. Resultingly, the gap between the seal surfaces is subjected to the conditions of crevice corrosion. In the art, crevice corrosion is understood as local corrosion of metal materials in a narrow gap between two surfaces that due to lack of oxygen cannot form a passivating layer that could protect the surfaces from corrosion. Such seal surfaces 1 can be found, e.g., in pipes and on flanges, valves, manhole covers and vapor pockets connected to process piping. Typically, the base material 2 of seal surface 1 is carbon steel which in itself is not particularly resistant to moist hydrofluoric acid. Obviously, the base material 2 of seal 1 may also be any other material typically used in the oil refinery industry such as structural, alloy or stainless steel.

To improve its corrosion resistance, the seal surface 1 is coated in laser coater equipment 5 with a coating layer 4 of a nickel alloy material such as a commercially available nickel-copper alloy known under tradename Monel 400. In nickel-copper alloys, the basic component is nickel having copper and trace amounts of other elements alloyed therewith. In Monel 400, for instance, the composition is about 64% nickel (Ni), about 31% copper (Cu) with trace amounts of iron (Fe), chromium (Cr), silicon (Si), carbon (C), sulfur (S) and manganese (Mn). Nickel-copper alloys have a high corrosion resistance to hydrofluoric acid and silicon hydrofluoric acid as well as to salt water and the like high-concentration chloride solutions. Furthermore, they are resistant to alkaline solutions having a concentration less than 50%.

The coating layer may also be nickel or some other nickel alloy material such as a nickel-molybdenum (Mo) alloy. Typical compositions of nickel-based coating material used in the invention are listed in the table below.

| Type | Tradename | Ni [%] | Cr [%] | Mo [%] | Fe [%] | C [%] | Cu [%] |
|---|---|---|---|---|---|---|---|
| Ni | Nickel 200 | 99.5 | | | | 0.08 | |
| | Nickel 201 | 99.5 | | | | 0.01 | |
| NiCu | Monel 400 | 64 | | | 2 | | 31 |
| NiMo | Hastelloy B-2 | 68 | | 28 | | 0.01 | |

The laser coater equipment 5 comprises a laser gun 6, wherefrom coating material in pulverized form is applied with the help of a carrier gas to an area of the seal surface 1 premelted by the laser beam 7. Prior to coating, the seal surface 1 can be machined to a desired roughness and cleaned in order to render desired properties to the coating material 4. The feed of the coating material may take place from aside the laser beam 7 or, alternatively, coaxially about the laser beam 7, whereby the flow of the coating material with the carrier gas surrounds the laser beam 7. Instead of using pulverized coating material, the coating material may also be introduced to the working area of the laser beam 7 as a sheet or wire. The carrier gas is carbon dioxide or argon. The seal surface 1 is moved relative to the laser beam 7 and/or the laser beam 7 is moved over the seal surface 1. The seal surface 1 to be coated may have a rotation-symmetrical or planar shape, for instance.

The scanning speed of the laser beam 7 over the seal surface 1 is advantageously 100 to 1500 mm/min. As the heat imported by the laser beam 7 is primarily absorbed by the workpiece being coated, the melted coating material 4 solidifies rapidly with the progress of the coating process. Moreover, since the laser beam 7 melts only a small area of the seal surface 1, the stresses imposed on coating material layer 4 due to solidification and cooling remain very small. In its molten state, the coating layer 4 is protected by the shielding gas. The width of a coating layer strip 4 applied in a single sweep of the beam is determined by the distance of the focus point of the laser beam 7 relative to the surface 2 being coated. Typically, the width of a single strip of the coating layer 4 formed by moving the laser gun 6 and/or the surface of the seal 1 to be coated is 2 to 3 mm. The thickness of the coating layer 4 formed by the laser coating method is typically 0.1 to 4 mm, most advantageously about 1 mm. When necessary, a greater number of coating layers 4 can be superposed on each other. The output power of laser beam 7 is typically 2 to 6 kW.

The center axis of the laser beam 7 is generally aligned obliquely in regard to the envelope surface of the seal 1 to be coated. In the context of the present invention, the term envelope surface is used in making reference to the surface delineating an ideal shape of the seal surface being handled wherefrom the actual shape of the seal surface may differ due to, e.g., manufacturing tolerances, wear or other deformations.

The coating material must be selected to be metallurgically compatible with the base material 2. The mutual compatibility may be improved by a proper choice of additives in the coating material or through altering its composition. The qualities achievable by means of the coating are determined by the application, base material, coating material and process parameters used.

FIGS. 2-5 illustrate surfaces that typically occur in an alkylation unit at an oil refinery and are advantageously coatable by virtue of the method according to the invention. In FIG. 2 is shown a piping flange having its seal surface 8 coated by means of the method elucidated in FIG. 1. During the operation of the alkylation unit, seal surface 8 is mated with another seal surface coated in the same fashion. The other surface to be fitted against seal surface 8 may be situated on the flange of a pipe or valve, for instance.

FIG. 3 shows a blind flange having its seal surface 9 coated using the method according to the invention. Respectively, FIG. 4 shows a manhole cover having its seal surface 10 coated using the method according to the invention. Furthermore, FIG. 5 shows a vapor pocket having its exterior surface 11 coated using of the method according to the invention. Also the seal surfaces of gate elements in a valve may be coated by virtue of the method according to the invention. Such surfaces are, e.g., the gate element of a valve and its mating seal surface.

What is claimed is:

1. A method for coating a seal surface (1) used in an alkylation process at an oil refinery by a coating layer (4) of a nickel-based material to improve the corrosion resistance of the seal surface (1), characterized in that the coating layer (4) is formed using a laser coating method in which coating material is applied to an area of the seal surface (1) premelted by the laser beam (7).

2. The method of claim 1, characterized in that the base material (2) of the seal surface (1) is carbon steel.

3. The method of claim 1 or 2, characterized in that the material of the coating layer (4) is a nickel-copper alloy.

4. The method of claim 1, 2 or 3, characterized in that the thickness of the coating layer (4) is 0.1 to 4 mm, most advantageously about 1 mm.

5. The method of any one of foregoing claims, characterized in that the hydrofluoric acid is used as a carrier medium in the alkylation process.

6. A seal surface (1) for use in an alkylation process at an oil refinery and having a coating layer (4) of a nickel-based material applied thereon, characterized in that the coating layer (4) is formed using a laser coating method.

7. The seal surface of claim 6, characterized in that the seal surface (1) is situated on a piping flange, valve, manhole cover or vapor pocket.

8. The seal surface of claim 6 or 7, characterized in that hydrofluoric acid is used in said alkylation process.
